(19) United States
(12) Patent Application Publication
(10) Pub. No.: US 2026/0280518 A1
(43) Pub. Date: Sep. 17, 2026

(54) ACOUSTIC WAVE DEVICES WITH VIA STRUCTURES

(71) Applicant: Qorvo US, Inc., Greensboro, NC (US)

(72) Inventors: Andriy Kryshtopin, Kirchseeon (DE); Vladimir Kolchuzhin, Hohenschaeftlarn (DE)

(21) Appl. No.: 19/551,203

(22) Filed: Feb. 26, 2026

Related U.S. Application Data
(60) Provisional application No. 63/770,223, filed on Mar. 11, 2025.

(51) Int. Cl. H03H 9/17; H03H 3/02

(52) U.S. Cl. CPC H03H 9/172; H03H 3/02

(57) ABSTRACT

Embodiments of the present disclosure provide an acoustic wave device. The acoustic wave device includes a first electrode, a second electrode, and a piezoelectric layer between the first electrode and the second electrode. The acoustic wave device also includes a substrate over the first electrode, and a via structure in contact with the first electrode and extending in the substrate.

### RELATED APPLICATION(S)

The present application claims priority to and the benefit of U.S. Provisional Application number 63/770,223, entitled “ACOUSTIC WAVE DEVICES WITH VIA STRUCTURES” and filed on Mar. 11, 2025, which is hereby incorporated by reference in its entirety.

### FIELD OF THE INVENTION

This disclosure relates to acoustic wave structures. In particular, this disclosure relates to acoustic wave devices with via structures.

### BACKGROUND

Acoustic filters, e.g., particularly Bulk Acoustic Wave (BAW) resonators or BAW filters, are used in high-frequency communication applications such as 3^{rd} Generation (3G), 4^{th} Generation (4G), and 5^{th} Generation (5G) wireless devices. In particular, a BAW filter is often employed to provide a flat passband, steep filter skirts, and squared shoulders at the upper and lower ends of the passband, and provide excellent rejection outside of the passband in a filter network. BAW filters also have relatively low insertion loss, tend to decrease in size as the frequency of operation increases, and are relatively stable over wide temperature ranges. These wireless devices often support various communication means such as cellular, wireless fidelity (Wi-Fi), Bluetooth, and/or near field communications, and accordingly, high performance of the BAW filters are needed.

Acoustic wave filters are widely used in filtering signals in communication (e.g., 5G networks) in electronic devices. As the systems continue to scale down, heat management may become increasingly important. Specifically, due to filter insertion loss (IL), a significant part of output power (Pout) of an acoustic wave filter is being transformed into undesired heat. This effect can cause increasing of die temperature and, thus, downshift of its frequency characteristic. If frequency characteristic goes down, filter loss at the upper band edge (UBE) goes up. This can cause more loss at the UBE, and the filter temperature can continue to increase. As a result, due to overheating, the filter might be susceptible to damage, and/or desired Pout can be difficult to achieve.

Therefore, there is a need for improvement in heat dissipation in acoustic wave filters.

### SUMMARY

Embodiments of the present disclosure provide an acoustic wave device. The acoustic wave device includes a first electrode, a second electrode, and a piezoelectric layer between the first electrode and the second electrode. The acoustic wave device also includes a substrate over the first electrode, and a via structure in contact with the first electrode and extending in the substrate. The via structure builds electrical and thermal connections into the both directions.

In some embodiments, the acoustic wave device further includes a second via structure through the piezoelectric layer and in contact with the first electrode and the second electrode, wherein the via structure is conductively (both, electrically and thermally) connected to the second electrode through the first electrode and the second via structure.

In some embodiments, the acoustic wave device further includes a metallization structure in contact with the second electrode.

In some embodiments, the via structure includes a metal.

In some embodiments, the via structure includes at least one of copper (Cu), aluminum (Al), aluminum copper (AlCu), gold (Au), silver (Ag), tungsten (W), or a combination thereof, or any other suitable electrically and thermally conductive material.

In some embodiments, the via structures and the metallization structure are aligned in a vertical direction perpendicular to a surface of the substrate that the first electrode is disposed on.

In some embodiments, the metallization structure includes at least one of copper (Cu), aluminum (Al), aluminum copper (AlCu), gold (Au), silver (Ag), tungsten (W), tin (Sn), lead (Pb), tin (Sn), titanium (Ti), or a combination thereof, or any other suitable electrically and thermally conductive material.

In some embodiments, the metallization structure and the via structure include a same material.

In some embodiments, the metallization structure is configured to transmit a signal, be connected to ground (GND), and/or conduct heat.

In some embodiments, the acoustic wave device further includes another electrode overlapped with one of the first electrode or the second electrode and insulated from the second via structure, wherein a bulk acoustic wave (BAW) resonator is formed by the other electrode, the one of the first electrode or the second electrode, and a portion of the piezoelectric layer located in an overlapped area.

In some embodiments, the acoustic wave device further includes at least one acoustic reflecting layer between the first electrode and the substrate.

Embodiments of the present disclosure provide a method for forming an acoustic wave device. The method includes: forming, over a substrate, a first electrode and a piezoelectric layer over the first electrode; forming a first via structure through the piezoelectric layer and in contact with the first electrode; forming a second electrode over the piezoelectric layer and in contact with the first via structure; and forming, in the substrate, a second via structure extending in the substrate and in contact with the first electrode.

In some embodiments, the forming of the second via structure includes patterning the substrate to form an opening in contact with the first electrode; and depositing a metal material in the opening.

In some embodiments, the method further includes forming a metallization structure in contact with the second electrode.

In some embodiments, the second via structure is formed after a formation of the second electrode.

In some embodiments, the second via structure is formed prior to a formation of the first electrode,

In some embodiments, the method further includes forming another electrode layer that is overlapped with one of the first electrode or the second electrode and insulated from the first via structure such that, a bulk acoustic wave (BAW) resonator is formed by the other electrode, the one of the first electrode or the second electrode, and a portion of the piezoelectric layer located in an overlapped area.

In some embodiments, the forming of the first electrode and the second electrode each includes depositing a respective layer of electrode material and patterning the layer to form one or more respective electrodes.

In some embodiments, the method further includes forming an acoustic reflecting layer between the substrate and the first electrode.

In some embodiments, the forming of the metallization structure includes soldering.

### BRIEF DESCRIPTION OF THE DRAWINGS

FIG. 1A illustrates a three-dimensional (3D) view of an exemplary bulk acoustic wave (BAW) filter device with via structures, according to embodiments of the present disclosure.

FIG. 1B illustrates a two-dimensional (2D) cross-sectional view of an exemplary BAW device with via structures, according to embodiments of the present disclosure.

FIG. 2 illustrates a flowchart of an exemplary fabrication process shown in FIGS. 3A-3G, according to embodiments of the present disclosure.

FIG. 3A illustrates a fabrication process and corresponding structure of forming an insulating layer over a substrate.

FIG. 3B illustrates a fabrication process of forming a reflector layer over the insulating layer.

FIG. 3C illustrates a fabrication process and corresponding structure of forming a first electrode layer over the reflector layer.

FIG. 3D illustrates a fabrication process and corresponding structure of forming a piezoelectric layer over the first electrode layer.

FIG, 3E shows a structure after forming a first via structure in the piezoelectric layer.

FIG. 3F shows a structure after forming a second electrode layer formed over the piezoelectric layer.

FIG. 3G shows a structure after one or more second via structures are formed in the substrate.

FIG. 3H shows a structure after second via structures are formed in the substrate.

### DETAILED DESCRIPTION

The following detailed description is illustrative in nature and is not intended to limit the scope, applicability, or configuration of inventive embodiments disclosed herein in any way. Rather, the following description provides practical examples, and those skilled in the art will recognize that some of the examples may have suitable alternatives. Embodiments will hereinafter be described in conjunction with the appended drawings, which are not to scale (unless so stated), wherein like numerals/letters denote like elements. However, it will be understood that the use of a number to refer to a component in a given drawing is not intended to limit the component in another drawing labeled with the same number. In addition, the use of different numbers to refer to components in different drawings is not intended to indicate that the different numbered components cannot be the same or similar to other numbered components. Examples of constructions, materials, dimensions and fabrication processes are provided for select elements and all other elements employ that which is known by those skilled in the art.

As used herein, the term “about” refers to a given amount of value that may vary based on the particular technology node associated with the semiconductor device. Based on a particular technology node, the term “about” can refer to a given amount of value that varies, for example, within 10-30% of the value (e.g., ±10%, ±20%, or ±20% of that value, or ±30%).

As used herein, the term “coupling” refers to combining or joining via electricity, and may be interchangeable with “electrically coupling,” “electrically connected,” “connected,” “conductively coupled,” and/or “conductively connected.”

As used herein, a “top” structure refers to an object located away from a substrate/layer, and a “bottom” structure refers to an object located closer to the substrate/layer.

Reference will now be made in greater detail to various embodiments of the subject matter of the present disclosure, some embodiments of which are illustrated in the accompanying drawings.

As used herein, “conductively connected to” may refer to that two or more components are linked in such a way that allows electrical current to flow between them, and may be used interchangeably with “electrically connected to”, “electrically coupled to”, “conductively coupled to”, and/or “coupled to”. As used herein, “thermally connected to” may refer to that two or more components are connected in a way that allows heat to transfer between them, and may be used interchangeably with “thermally coupled to”.

Existing BAW filers may have undesirably high hot spots and therefore extremely high temperature and temperature gradient over die due to various factors such as insertion loss and poor heat dissipation. To improve heat dissipation, embodiments of the present disclosure provide a BAW device with via structures that can more efficiently dissipate the heat generated in the BAW device without sacrificing the size of the BAW device. In fact, the reduction of thermal resistance may allow to reduce filter/device die temperature, downshift of its frequency characteristic, and shrink die size. This reduction of thermal resistance may improve module performance over temperature, avoid Pout drop, and may reduce current consumption in the module. Also, this solution may provide an opportunity to reduce filter die size, which can be an indication of cost, and improve transmitter-receiver (TX-RX) isolation due to better centering of the filter UBE.

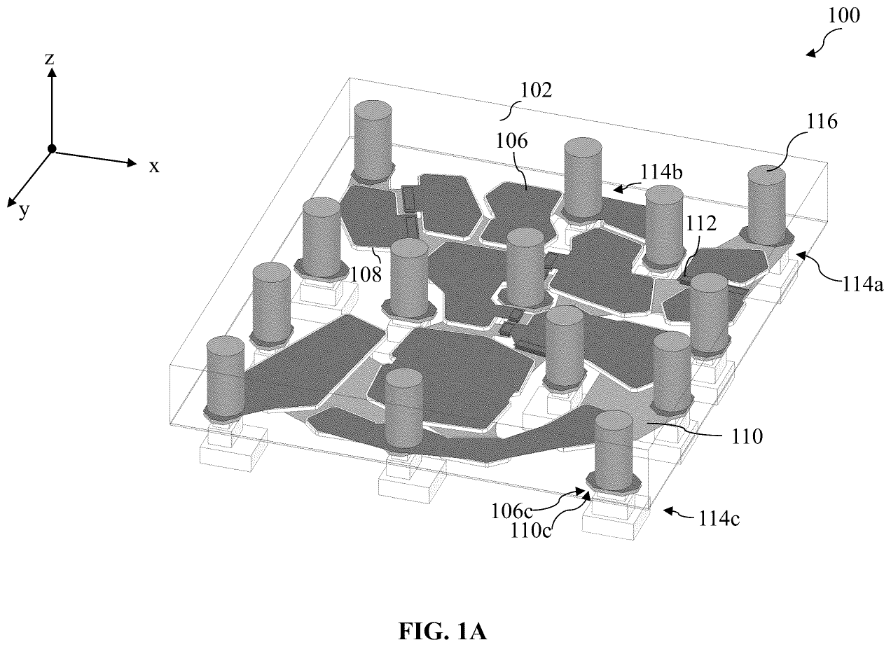

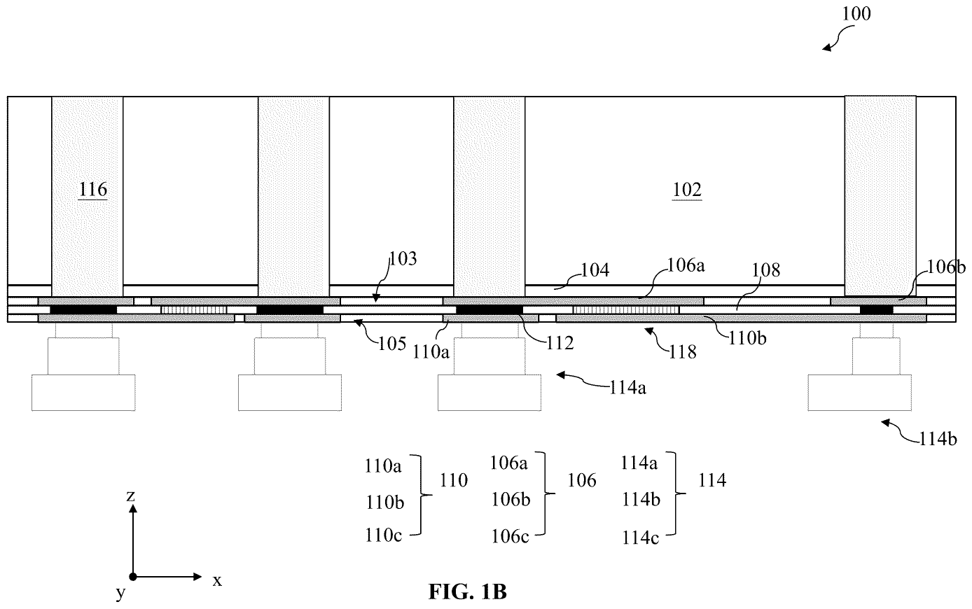

FIG. 1A illustrates a 3D view of a BAW device 100, and FIG. 1B shows a 2D cross-sectional view of BAW device 100, according to embodiments of the present disclosure. BAW device 100 may include one or more via structures that may significantly improve temperature gradient over die and heat dissipation. For ease of illustration, FIGS. 1A and 1B are described together.

BAW device 100 may include a first electrode layer 103 and a second electrode layer 105 arranged in the vertical direction (e.g., z direction), and a piezoelectric layer 108 disposed between first electrode layer 103 and second electrode layer 105. First electrode layer 103 may include a plurality of first electrodes 106 disposed over a first surface of piezoelectric layer 108, and second electrode layer 105 may include a plurality of second electrodes 110 disposed over a second surface of piezoelectric layer 108.

First electrodes 106 may include a first electrode 106a and a first electrode 106b, insulated from each other. Second electrodes 110 may include a second electrode 110a and a second electrode 110b, insulated from each other. A first electrode 106a may be directly conductively connected to a second electrode 110a through a via 112 for signal transmission, and may form a BAW resonator 118 with a second electrode 110b. The projections of first electrode 106a and second electrode 110b may have an overlapping area on the x-y plane, and may form BAW resonator 118 with the portion of piezoelectric layer 108 disposed in the overlapping area. An acoustic wave may be formed propagating in piezoelectric layer 108 confined in the overlapping area. A first electrode 106b may not form any BAW resonator with a second electrode 110a, and may be directly conductively connected to second electrode 110b through via 112 to be grounded. In some embodiments, first electrode 106a of BAW resonator 118 is conductively connected to a signal, and second electrode 110b of BAW resonator 118 is grounded. BAW resonator 118 may be part of a BAW filter. In operation, in some embodiments, BAW resonator 118 may be controlled by the signal (e.g., to turn on and off) to filter certain wavelengths.

In some embodiments, first electrode layer 103 includes a first electrode 106c and second electrode layer 105 includes a second electrode 110c. First electrode 106c and second electrode 110c may overlap with each other in the x-y plane, and may be in contact with each other (e.g., thermally coupled to) through via 112. First electrode 106c and second electrode 110c may not be part of any BAW resonator, or be conductively connected to other components. Instead, first electrode 106c and second electrode 110c are for thermal conduction, and can be formed in a location that is susceptible to high temperature. In some embodiments, first electrode 106c and second electrode 110c are further connected to metallization structures and/or via structures to further conduct heat. Details are described below.

First electrodes 106 and second electrodes 110 may each include a suitable conductive material such as one or more of copper (Cu), tungsten (W), aluminum copper (AlCu), molybdenum (Mo), and/or platinum (Pt). In some embodiments, first electrode 106 and second electrode 110 may each include tungsten and/or aluminum copper. Piezoelectric layer 108 may include a suitable piezoelectric material such as aluminum nitride (AIN), zinc oxide (ZnO), aluminum scandium nitride (AlScN) and/or other suitable materials. In some embodiments, piezoelectric layer 108 includes AIN. In some embodiments, first electrode layer 103 and second electrode layer 105 each include a suitable insulating material such as silicon oxide, silicon nitride, silicon oxynitride, epoxy, resin, and/or the like, that is disposed around the electrodes for insulation.

Via 112 may be disposed in piezoelectric layer 108 and may have sufficiently high electrical conductivity and thermal conductivity. Via structure 112 may be used to thermally (and/or electrically) connect a first electrode (e.g., 106a, 106b, and/or 106c) with a respective second electrode (e.g., 110a, 110b, and/or 110c) for dissipating heat generated by the BAW resonator 118 and/or electrodes. Via 112 may also conduct electricity between first electrodes (e.g., 106a, 106b) and second electrodes (e.g., 110a, 110b). Via structure 112 may include a suitable material, e.g., conductive when biased, such as copper (Cu), aluminum (Al), gold (Au), silver (Ag), tungsten (W), polysilicon, and/or the like.

BAW device 100 may include one or more metallization structures 114 disposed in contact with second electrodes 110. Metallization structures 114 may be conductively and/or thermally connected to second electrodes 110a, 110b, and 110c. Metallization structures 114 may facilitate electrical connections between second electrodes 110a and/or 110b (e.g., and BAW resonators 118, and first electrodes 106a and/or 106b) and an external circuit for signal transmission and/or operation control. For example, metallization structures 114 may be conductively connected and/or in contact with a laminate structure with an embedded circuit. Meanwhile, metallization structures 114 may also facilitate heat conduction/dissipation from the electrodes (e.g., 106 and/or 110), and/or piezoelectric layer 108, e.g., into the laminate structure. In some embodiments, metallization structures 114 include under bump metallization or “bumps.”

Depending on the connection, metallization structures 114 may be connected to the ground (GND) or may be connected to a signal. For example, metallization structure 114 may include a metallization structure 114a that is in contact with second electrode 110a (and first electrode 106a through via 112), a metallization structure 114b that is in contact with second electrode 110b (and first electrode 106b through via 112), and a metallization structure 114c that is in contact with second electrode 110c (and first electrode 106c through via 112). Metallization structure 114a may be configured to transmit a signal from/to second electrode 110a and is referred to as a “signal bump.” Metallization structure 114b may be configured to be connected to ground (GND), and is referred to as a “ground bump.” Metallization structure114c may be used for heat conduction/dissipation, and may be referred to as a “thermal bump.” For example, metallization structure 114c may not be electrically connected to a signal or ground (GND), and is configured to conduct heat generated by other parts of BAW device 100 (e.g., BAW resonators). In various embodiments, metallization structures 114a, 114b, and/or 114c are disposed at locations that are susceptible to overheating, and are used to conduct heat from the electrodes (e.g., 106 and/or 110) and piezoelectric layer 108. In some embodiments, metallization structures 114a, 114b, and/or 114c are aligned with respective vias 112 (e.g., connecting a second electrode and a first electrode) in the vertical direction, and may be disposed in locations that may be susceptible to overheating.

In some embodiments, metallization structures 114a, 114b, and 114c include a suitable metal such as titanium (Ti), chromium (Cr), titanium-tungsten (TiW), nickel (Ni), tantalum (Ta), titanium nitride (TiN), tungsten (W), copper (Cu), gold (Au), silver (Ag), tin (Sn), etc.

BAW device 100 may also include an intermediate layer 104 disposed over first electrode layer 103. Intermediate layer 104 may include any suitable materials used as reflectors and/or insulation. For example, intermediate layer 104 may include a reflector layer disposed over first electrode layer 103 and an insulating layer disposed over the reflector layer. The reflector layer may provide acoustic reflection for the acoustic wave propagation between first electrode 106a and second electrode 110b. The insulating layer may provide insulation between a substrate 102 and BAW resonator 118. In some embodiments, the reflector layer includes one or more materials that are acoustically reflective, such as copper (Cu), tungsten (W), aluminum copper (AlCu), and/or the like. For example, the reflector layer may include alternatingly arranged first stack layers and second stack layers, while the first stack layers include tungsten, and the second stack layers include AlCu. In some embodiments, the insulating layer includes a suitable insulating material such as silicon oxide, silicon nitride, silicon oxynitride, and/or so on.

BAW device 100 may further include a substrate 102 disposed over intermediate layer 104. Substrate 102 may provide the foundation for the formation of BAW resonator 118. Substrate 102 may include a suitable material with desirably low dielectric permittivity and can provide sufficient mechanical support for the fabrication process. For example, substrate 102 may include silicon, glass, epoxy, ceramics, plastics, gallium arsenide (GaAs), Teflon(PFTE), or the like.

BAW device 100 may further include one or more via structures 116 extending in substrate 102. Via structure 116 may be in contact with first electrode 106 to conduct heat generated from BAW resonator 118 and/or the electrodes (e.g., 106 and/110). In some embodiments, via structure 116 is electrically and thermally connected to first electrodes 106, and second electrodes 110 through vias 112. Because vias 112 may be disposed in areas that are susceptible to overheating, via structure 116 can improve heat dissipation from the electrodes 106, 110, and/or via 112, into substrate 102. In various embodiments, via structure 116 may extend partially or fully through substrate 102. To improve thermal conductivity, in some embodiments, via structure 116 is at least substantially aligned with via 112 in the vertical direction. Via structure 116 may include a suitable shape to facilitate heat dissipation. In some embodiments, as shown in FIG. 1A, via structure 116 has a pillar shape. Via structure 116 may include a material of sufficiently high thermal conductivity. In some embodiments, via structure 116 includes a metal material such as copper (Cu), aluminum (Al), gold (Au), silver (Ag), tungsten (W), or any combination thereof.

In various embodiments, metallization structure 114 (e.g., 114a, 114b, and/or 114c), the respective via 112, and the respective via structure 116, may be aligned in the vertical direction to improve heat dissipation. Via structure 116, the respective via 112, and the respective metallization structure 114 may include the same material or may include different materials. In some embodiments, via structure 116 is referred to as a “bump extension,” or “via extension structure.”

Via structures 116 can improve heat dissipation in BAW device 100. Because via structures 116 are formed in locations that are susceptible to overheating (e.g., aligned with metallization structures 114 that are previously disposed for heat dissipation), additional heat dissipation paths can be formed by conducting heat into substrate 102. Overheating in BAW device 100 can be alleviated. Calculated data shows that the temperature of BAW 100 decreases by about 30 degrees Celsius with via structures 116, compared to that without via structure 116.

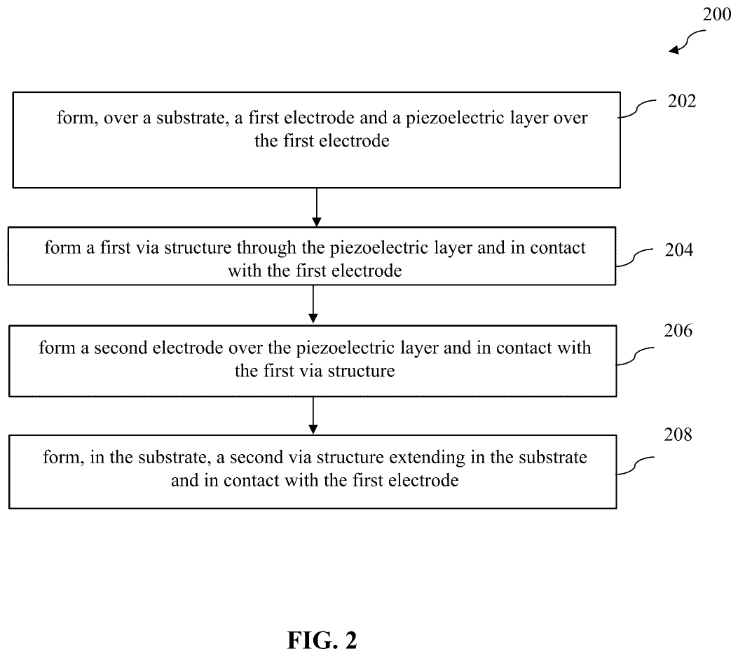

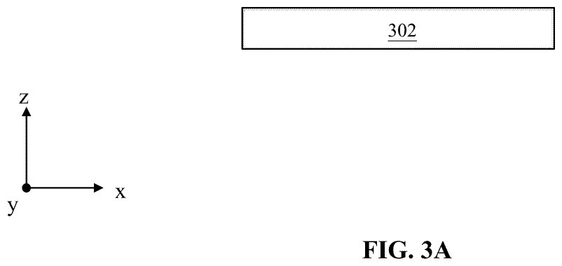

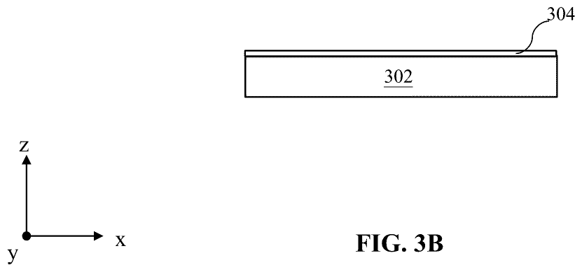

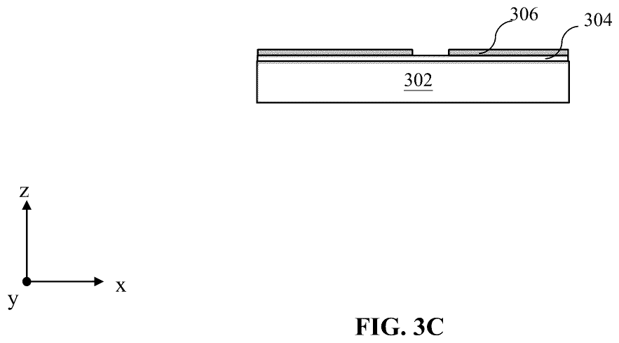

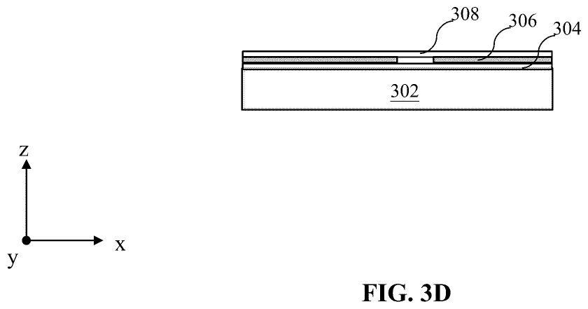

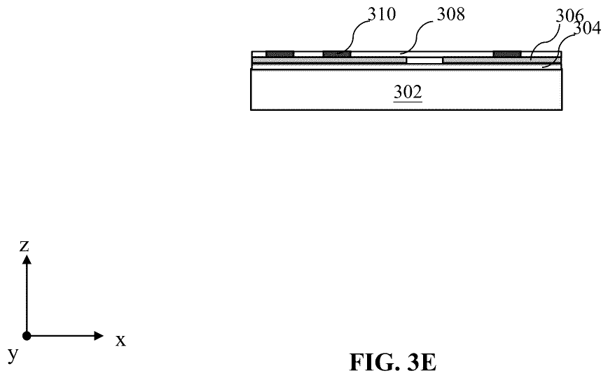

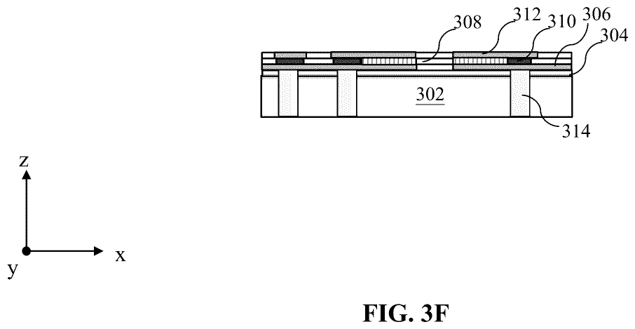

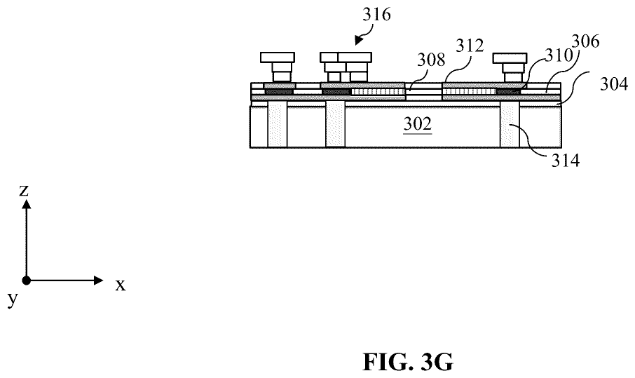

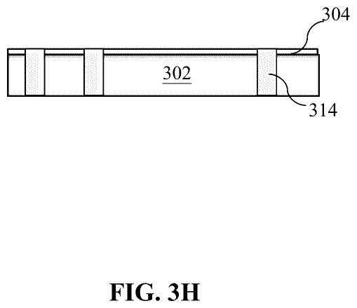

FIG. 2 is a flowchart of a method 200 for forming a BAW device similar to BAW device 100, according to some embodiments of the present disclosure. Method 200 is merely an example, and is not intended to limit the present disclosure beyond what is explicitly recited in the claims. Additional operations can be provided before, during, and after the method 200, and some operations described can be replaced, eliminated, or moved around for additional embodiments of method 200. Method 200 will be described in more detail below. FIGS. 3A-3H illustrate structures of the BAW device at different stages of alternative fabrication processes.

At step 202, a first electrode and a piezoelectric layer over the first electrode are formed over a substrate. FIGS. 3A-3D illustrate corresponding structures

As shown in FIG. 3A, an insulating layer (not shown) is formed over a substrate 302. In some embodiments, substrate 302 includes silicon, and the insulating layer include silicon oxide. The formation of the insulating layer may include one or more suitable deposition processes such as atomic layer deposition (ALD), chemical vapor deposition (CVD), physical vapor deposition (PVD).

As shown in FIG. 3B, a reflector layer 304 is formed over the insulating layer. Reflector layer 304 may include one or more metal materials such as tungsten and aluminum copper. In some embodiments, reflector layer 304 include alternatingly arranged tungsten layers and aluminum copper layers. The deposition of reflector layer 304 may include one or more suitable deposition processes such as atomic layer deposition (ALD), chemical vapor deposition (CVD), physical vapor deposition (PVD), electroplating, electroless plating, e-beam evaporation, or a combination thereof.

As shown in FIG. 3C, a first electrode layer 306 is formed over reflector layer 304. First electrode layer 306 may include a plurality of first electrodes insulated from one another. First electrode layer 306 may be formed by a deposition of a suitable electrode material layer, and patterning the electrode material layer to form the first electrodes. In some embodiments, the electrode material layer includes copper, and the deposition may include one or more suitable deposition processes such as atomic layer deposition (ALD), chemical vapor deposition (CVD), physical vapor deposition (PVD), electroplating, electroless plating, e-beam evaporation, or a combination thereof. The patterning of the electrode material layer may include a photolithography process followed by a suitable etching process (e.g., dry etch and/or wet etch). In some embodiments, the formation of first electrode layer 306 also includes depositing an insulating material, such as silicon oxide, and patterning the insulating material before depositing the electrode material. The deposition of the insulating material may include one or more suitable deposition processes such as atomic layer deposition (ALD), chemical vapor deposition (CVD), physical vapor deposition (PVD), and/or the like. Optionally, an etching process and/or a planarization process (e.g., a chemical mechanical polishing) is used to remove excess material.

As shown in FIG. 3D, a piezoelectric layer 308 is formed over first electrode layer 306. Piezoelectric layer 308 may include a suitable piezoelectric material such as AlN, and the deposition of piezoelectric layer 308 may include one or more suitable deposition processes such as atomic layer deposition (ALD), chemical vapor deposition (CVD), physical vapor deposition (PVD), and/or the like.

At step 204, a first via structure is formed through the piezoelectric layer and in contact with the first electrode. FIG. 3E shows a corresponding structure.

As shown in FIG. 3E, a first via structure 310 is formed in piezoelectric layer 308. First via structure 310 may be in contact with a first electrode. First via structure 310 may include a suitable conductive material such as copper, and can be formed by patterning piezoelectric layer 308 to form openings that expose first electrodes, and depositing the conductive material to fill the openings. In some embodiments, first via structure 310 is disposed at a location that is susceptible to overheating. In some embodiments, the patterning process includes a photolithography process followed by an etching process (e.g., dry etch and/or wet etch). In some embodiments, the deposition of the conductive material includes one or more suitable deposition processes such as atomic layer deposition (ALD), chemical vapor deposition (CVD), physical vapor deposition (PVD), electroplating, electroless plating, e-beam evaporation, or a combination thereof.

At step 206, a second electrode is formed over the piezoelectric layer and in contact with the first via structure. FIG. 3F shows a corresponding structure.

As shown in FIG. 3F, a second electrode layer 312 is formed over piezoelectric layer 308. Second electrode layer 312 may include a plurality of second electrodes insulated from one another. A second electrode may be in contact with a first via structure 310. Second electrode layer 312 may be formed by a deposition of a suitable electrode material layer, and patterning the electrode material layer to form the second electrodes. In some embodiments, the electrode material layer includes copper, and the deposition may include one or more suitable deposition processes such as atomic layer deposition (ALD), chemical vapor deposition (CVD), physical vapor deposition (PVD), electroplating, electroless plating, e-beam evaporation, or a combination thereof. The patterning of the electrode material layer may include a photolithography process followed by a suitable etching process (e.g., dry etch and/or wet etch). In some embodiments, the formation of second electrode layer 312 also includes depositing an insulating material, such as silicon oxide, and patterning the insulating material before depositing the electrode material. The deposition of the insulating material may include one or more suitable deposition processes such as atomic layer deposition (ALD), chemical vapor deposition (CVD), physical vapor deposition (PVD), and/or the like. Optionally, an etching process and/or a planarization process (e.g., a chemical mechanical polishing) is used to remove excess material.

At step 208, a second via structure is formed in the substrate, extending in the substrate and in contact with the first electrode. FIG. 3G shows a corresponding structure.

As shown in FIG. 3G, one or more second via structures 314 are formed in substrate 302. Second via structures 314 may be formed by patterning substrate 302 to form openings that expose a respective first electrode, and fill the openings with a suitable conductive material. In some embodiments, the openings that expose the first electrodes are at least substantially aligned with the respective first via structures 310 that are in contact with the first electrodes. Substrate 302 may be patterned using a suitable etching process such as dry etch and/or wet etch. In some embodiments, the second via structure 314 includes copper, and can be deposited by one or more suitable deposition processes such as atomic layer deposition (ALD), chemical vapor deposition (CVD), physical vapor deposition (PVD), electroplating, electroless plating, e-beam evaporation, or a combination thereof.

In some embodiments, a plurality of metallization structures 316 are formed over second electrode layer 312. As shown in FIG. 3G, metallization structure 316 may be in contact with a second electrode. Metallization structure 316 may include Sn, and the formation of metallization structure may include soldering. In various embodiments, metallization structures 316 can be formed prior to or after the formation of second via structures 314. In some embodiments, metallization structures 316 are aligned with second via structures 314 (e.g., and first via structures 310) in the vertical direction.

In some embodiments, second via structures 314 are formed after the formation of reflector layer 304 and prior to the formation of any electrode layers. As shown in FIG. 3H, second via structures 314 can be formed through substrate 302 and reflector layer 304 after the step shown in FIG. 3B and prior to the step shown in FIG. 3C. Accordingly, no second via structures 314 need to be formed in the step shown in FIG. 3G. Second via structures 314 may be disposed at locations that correspond to the first electrodes, first via structures 310, and metallization structures 316. Substrate 302 may be patterned using a suitable etching process such as dry etch and/or wet etch. In some embodiments, second via structure 314 includes copper, and can be deposited by one or more suitable deposition processes such as atomic layer deposition (ALD), chemical vapor deposition (CVD), physical vapor deposition (PVD), electroplating, electroless plating, e-beam evaporation, or a combination thereof.

1. An acoustic wave device, comprising:
a first electrode;
a second electrode;
a piezoelectric layer between the first electrode and the second electrode;
a substrate over the first electrode; and
a via structure in contact with the first electrode and extending in the substrate.

2. The acoustic wave device of claim 1, further comprising a second via structure through the piezoelectric layer and in contact with the first electrode and the second electrode, wherein the via structure is conductively connected to the second electrode through the first electrode and the second via structure.

3. The acoustic wave device of claim 1, further comprising a metallization structure in contact with the second electrode.

4. The acoustic wave device of claim 1, wherein the via structure comprises a metal.

5. The acoustic wave device of claim 4, wherein the via structure comprises at least one of copper (Cu), aluminum (Al), aluminum copper (AlCu), gold (Au), silver (Ag), tungsten (W), or a combination thereof.

6. The acoustic wave device of claim 3, wherein the via structures and the metallization structure are aligned in a vertical direction perpendicular to a surface of the substrate that the first electrode is disposed on.

7. The acoustic wave device of claim 3, wherein the metallization structure comprises at least one of copper (Cu), aluminum (Al), aluminum copper (AlCu), gold (Au), silver (Ag), tungsten (W), tin (Sn), lead (Pb), tin (Sn), titanium (Ti), or a combination thereof.

8. The acoustic wave device of claim 3, wherein the metallization structure and the via structure comprise a same material.

9. The acoustic wave device of claim 3, wherein the metallization structure is configured to transmit a signal, be connected to ground (GND), or conduct heat.

10. The acoustic wave device of claim 2, further comprising another electrode overlapped with one of the first electrode or the second electrode and insulated from the second via structure, wherein a bulk acoustic wave (BAW) resonator is formed by the other electrode, the one of the first electrode or the second electrode, and a portion of the piezoelectric layer located in an overlapped area.

11. The acoustic wave device of claim 1, further comprising an acoustic reflecting layer between the first electrode and the substrate.

12. A method for forming an acoustic wave device, comprising:
forming, over a substrate, a first electrode and a piezoelectric layer over the first electrode;
patterning the piezoelectric layer to form a first via structure through the piezoelectric layer and in contact with the first electrode;
forming a second electrode over the piezoelectric layer and in contact with the first via structure;
patterning the substrate to form, in the substrate, a second via structure extending in the substrate and in contact with the first electrode.

13. The method of claim 12, wherein the forming of the second via structure comprises
patterning the substrate to form an opening in contact with the first electrode; and
depositing a metal material in the opening.

14. The method of claim 12, further comprising forming a metallization structure in contact with the second electrode.

15. The method of claim 12, wherein the second via structure is formed after a formation of the second electrode.

16. The method of claim 12, wherein the second via structure is formed prior to a formation of the first electrode.

17. The method of claim 12, further comprising forming another electrode layer that is overlapped with one of the first electrode or the second electrode and insulated from the first via structure such that, a bulk acoustic wave (BAW) resonator is formed by the other electrode, the one of the first electrode or the second electrode, and a portion of the piezoelectric layer located in an overlapped area.

18. The method of claim 12, wherein the forming of the first electrode and the second electrode each comprises depositing a respective layer of electrode material and patterning the layer to form one or more respective electrodes.

19. The method of claim 12, further comprising forming an acoustic reflecting layer between the substrate and the first electrode.

20. The method of clam 14, wherein the forming of the metallization structure comprises soldering.
